(19) United States
(12) Patent Application Publication
(10) Pub. No.: US 2022/0130741 A1
(43) Pub. Date: Apr. 28, 2022

(54) PACKAGE STRUCTURE FOR PASSIVE COMPONENT TO DIE CRITICAL DISTANCE REDUCTION

(71) Applicant: QUALCOMM Incorporated, San Diego, CA (US)

(72) Inventors: Aniket PATIL, San Diego, CA (US); Jonghae KIM, San Diego, CA (US); Hong Bok WE, San Diego, CA (US)

(21) Appl. No.: 17/081,340

(22) Filed: Oct. 27, 2020

(51) Int. Cl. H01L 23/498; H01L 21/48; H01L 23/00

(52) U.S. Cl. CPC H01L 23/49822; H01L 21/4857; H01L 23/49838; H01L 23/642; H01L 24/81; H01L 24/83; H01L 24/92

(57) ABSTRACT

Disclosed is a package and methods for making same. A package includes: a substrate having a first region comprising N number of metallization layers and a second region comprising M number of metallization layers, where M is less than N; a passive component located within the second region on a first surface of the substrate; and a die located within the second region on a second surface of the substrate opposite the first surface of the substrate, the die being electrically coupled to the passive component by at least one of the M number of metallization layers within the second region.

### FIELD OF DISCLOSURE

This disclosure relates generally to package devices, and more specifically, but not exclusively, to package structures for passive component to die critical distance reduction and fabrication techniques thereof.

### BACKGROUND

Integrated circuit technology has achieved great strides in advancing computing power through miniaturization of active components. There is a constant demand for chipsets that are faster, more capable, and higher performance, yet with smaller and smaller packaging sizes. One packaging solution has been to use so-called “flip-chip” devices, in which a chip is directly mounted pad-side-down onto a substrate rather than being mounted in a package that uses wire bonds to make electrical connections.

Critical distance is a term that refers to the distance between a terminal of an active device and a terminal of a passive component that is electrically coupled to the terminal of the active device. It is beneficial to minimize critical distances because doing so reduces loop inductance and parasitic capacitance, which improves performance.

FIG. 1 illustrates such a conventional package 100 based on a laminate substrate 102 onto which a flip-chip device, die 104 has, been mounted via conventional methods involving die bumps on the die 104 and bonding pads on the laminate substrate 102. Passive components 106, such as line-side capacitors (LSCs), are mounted as close to the die 104 as possible in order to keep parasitic capacitances and inductances low in order to avoid constraining the frequency of operation of the device, distorting signals between devices, and other impairments caused by parasitics. For this reason, the die 104 and passive components 106 for that die are typically mounted on the opposite sides of the same laminate substrate 102. This allows the passive components 106 to be separated from the die 104 by the sum total of the thickness of the electrical connection from the die 104 to the laminate substrate 102, the thickness of the laminate substrate 102, and the thickness of the electrical connection from the laminate substrate 102 to the passive component 106. This total distance between the die 104 and the passive component 106 is referred to as the critical distance. For conventional packages 100, these distances are, respectively, 40 μm for the die bump connecting the die 104 to the laminate substrate 102, 120 μm for the substrate 102, and 30 μm for the solder connection between the laminate substrate 102 and the passive component 106, resulting in a critical distance of approximately 200 μm.

FIG. 2 illustrates another conventional package 200 called fan-out wafer level packaging (FO-WLP), in which multiple redistribution layers 202—typically three or more layers in a stack—are built up on top of a bump-less die 204, to which a passive component 106 is mounted using solder joints. Here, the critical distance is the total of the thickness of the electrical connection from the die 204 to the redistribution layers 202 (effectively zero), the thickness of the stack of redistribution layers 202 (typically 50 μm), and the thickness of the electrical connection from the redistribution layers 202 to the passive component 106 (typically 30 μm), i.e., approximately 80 μm.

However, as chipset speeds continue to increase, the critical distance will continue to be a constraining factor to limit performance and to contribute to power consumption. Thus, there is a need for methods, systems, and apparatus that overcome the deficiencies of conventional packages, which are constrained by large critical distances.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In accordance with the various aspects disclosed herein, at least one aspect includes a package including: a substrate having a first region having a number N of metallization layers and a second region having a number M of metallization layers, where M is less than N; a passive component disposed within the second region on a first surface of the substrate; and a die disposed within the second region on a second surface of the substrate opposite the first surface of the substrate, the die being electrically coupled to the passive component by at least one of the number M of metallization layers within the second region.

In accordance with the various aspects disclosed herein, at least one aspect includes, a method for fabricating a package, the method including: providing a substrate having a first region having a number N of metallization layers and a second region having a number M of metallization layers, where M is less than N; providing a passive component disposed within the second region on a first surface of the substrate; and providing a die disposed within the second region on a second surface of the substrate opposite the first surface of the substrate, the die being electrically coupled to the passive component by at least one of the number M of metallization layers within the second region.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein like reference numbers represent like parts, which are presented solely for illustration and not limitation of the disclosure.

FIG. 1 illustrates a conventional package;

FIG. 2 illustrates another conventional package;

FIG. 3 illustrates an exemplary package according to one or more aspects of the disclosure;

FIG. 4 illustrates a flowchart of an exemplary partial method for manufacturing a package according to one or more aspects of the disclosure;

FIGS. 5A through 5C illustrate fabrication techniques in accordance with one or more aspects of the disclosure;

FIG. 6 illustrates an exemplary mobile device in accordance with one or more aspects of the disclosure; and

FIG. 7 illustrates various electronic devices that may be integrated with any of the aforementioned integrated device or semiconductor device in accordance with one or more aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

To address the deficiencies of conventional packages, and specifically to reduce the critical distance between an active device, e.g., a die, and a passive component associated with that die, the instant disclosure presents an improved package that uses the minimum number of layers needed to connect the active and passive components, which causes the thickness of the package between the active and passive components to be minimized, while other portions of the package use more layers and are therefore thicker. The instant disclosure also presents a process to create such an improved package: the process includes building up layers on a passive component terminal, obviating the need for a solder joint connection to the passive component. Remaining layers are built-up adjacent to passive component, which utilizes 3D space adjacent to passive component. This gives a derived benefit of structure, e.g., overall package height reduction. Moreover, a die-to-wafer attach process is used to attach a die to the improved package, which results in a much smaller stand-off height (e.g., ˜5 um) compared to conventional flip-chip attach (e.g., ˜40 um). The combination of these techniques result in a structure having a critical distance of ˜20 um, which is 4× smaller than conventional package solutions.

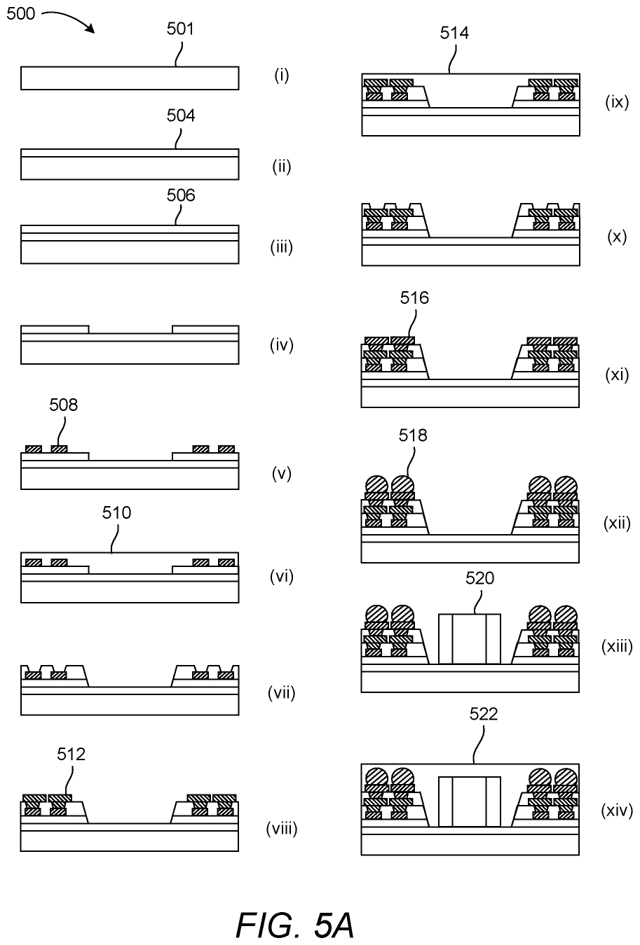

FIG. 3 illustrates an exemplary package according to one or more aspects of the disclosure. In FIG. 3, a package 300 includes a substrate 302 having a first region 304 comprising a number N of metallization layers and a second region 306 comprising a number M of metallization layers 303, where M is less than N. The substrate 302, in some aspects, includes one or more metallization layers 303 separated by one or more dielectric layers (not specifically illustrated). The metallization layers 303 may be configured as traces, pads and the like. The metallization layers 303 may be coupled to each other and/or to external connections by one or more vias. In some aspects, the metallization layers 303 may be configured as a redistribution layer (RDL) to redistribute signals, power and like. Package 300 also includes a passive component 308 located within the second region 306 and on a first surface of the substrate 302. In FIG. 3, the passive component 308 is on the bottom surface of the substrate 302 as oriented in this figure. Package 300 also include a die 310 located within the second region 306 and on a second surface of the substrate 302 opposite the first surface of the substrate 302. In FIG. 3, the die 310 is on the top surface of the substrate 302 as oriented in this figure. The passive component 308 and the die 310 are electrically coupled to each other by at least one of the M number of metallization layers 303 within the second region 306. As shown in FIG. 3, the first region 304 has a first thickness T1 and the second region 306 has a second thickness T2 less than T1. Thus, in FIG. 3, the critical distance between the passive component 308 and the die 310 is T2.

According to some aspects, the number of metallization layers 303 within the second region 306, M, is one, in which case the number of metallization layers 303 within the first region 304, N, is two or more. According to some aspects, the number of metallization layers 303 within the second region 306, M, is more than one, in which case the number of metallization layers 303 within the first region 304, N, is more than two. According to some aspects, the die 310 is electrically coupled to the package 300 using a die-to-wafer connection, which does not use solder joints. According to some aspects, the die 310 is part of a flip-chip package. According to some aspects, the passive component 308 is a line-side component, such as a line-side capacitor, resistor, or inductor. According to some embodiments, the metallization layers 303 use copper conductors. According to some embodiments, the substrate 302 is made of pre-preg (PPG).

Package 300 provides several technical advantages, including but not limited to the following. By creating regions having a reduced number of metallization layers 303, in which a die 310 and its corresponding passive component 308 are located, the critical distance between the die 310 and the passive component 308 is greatly reduced. In one example, the critical distance is four times smaller compared to conventional packages, i.e., 20 μm for package 300 versus 80 μm for conventional fan-out wafer-level packaging (FO-WLP). Because the component, either the die 310 or the passive component 308, is located on a thinner, inset region of the substrate 302, the overall height of the package 300 is potentially reduced compared to conventional packages that have no inset region. Moreover, the number of layers M in the second region 306 may be just the minimum layers needed to make necessary connections between the die 310 and the passive component(s) 308, which can be a few as one. Also, because the die 310 is attached last, as will be described in more detail below, package yield may increase.

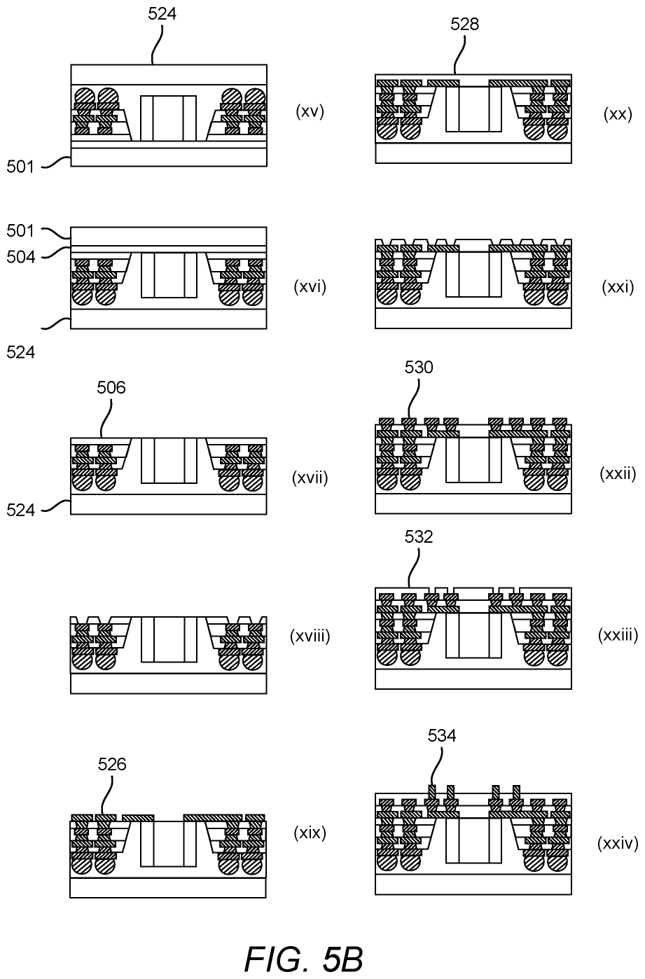

FIG. 4 illustrates a flowchart of an exemplary partial method 700 for manufacturing a package in accordance with some examples of the disclosure. As shown in FIG. 4, the partial method 400 may begin in block 402 with providing a substrate 302 having a first region 304 having a number N of metallization layers and a second region 306 having a number M of metallization layers, where M is less than N. The partial method 400 may continue in block 404 with providing a passive component 308 located within the second region 306 and on a first surface of the substrate 302. The partial method 400 may continue in block 406 with providing a die 310 located within the second region 306 and on a second surface of the substrate 302 opposite the first surface of the substrate 302, where the passive component 308 and the die 310 are electrically coupled to each other by at least one of the M number of metallization layers in the second region 306 of the substrate 302. It will be understood that where M=1, the passive component 308 will be electrically coupled to the die 310 using the single metallization layer. It will also be understood that where M>1, the passive component 308 may be electrically coupled to the die 310 using any one or more of the metallization layers available within the second region 306 of the substrate 302.

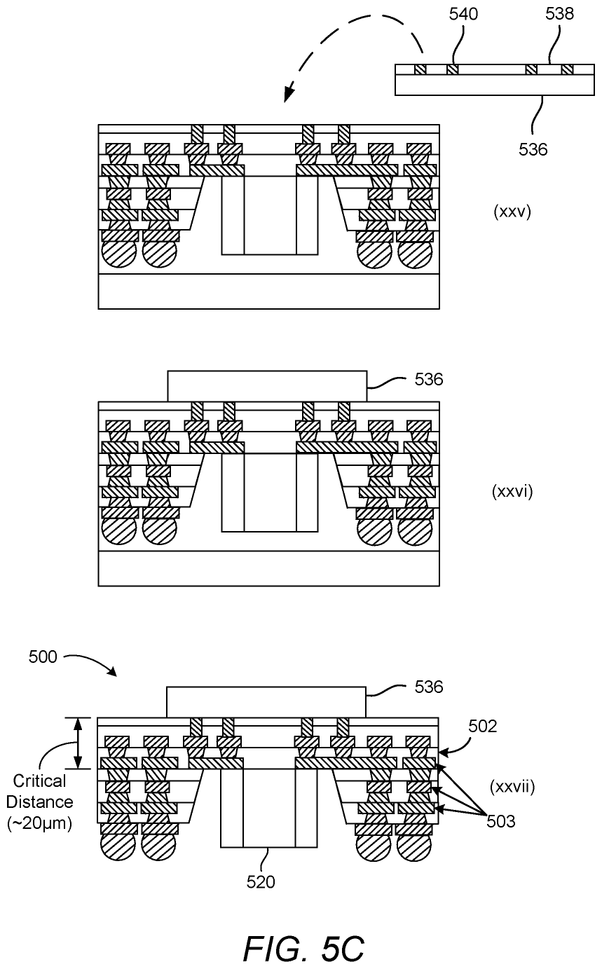

FIGS. 5A through 5C illustrate fabrication techniques in accordance with one or more aspects of the disclosure. Referring to FIG. 5A, in a partial process 500 portion (i), a first carrier 501 is provided. In process portion (ii), an adhesive layer 504 is provided above the first carrier 501. In process portion (iii), a first component-side photo-imaged dielectric (PID) 506 is provided above the adhesive layer 504. In process portion (iv), openings are created in the first component-side PID 506, e.g., using a photolithography process, including but not limited to a conventional photolithography process involving a photoresist laminate or coating, ultraviolet (UV) light exposure, a develop step, etc. In process portion (v), first layer conductors 508 are created on the first component-side PID 506. These first layer conductors 508 may be a metal layer or a metallization layer, for example, and may be formed using gold, silver, copper, aluminum, or other conductive materials. In process portion (vi), a second component-side PID 510 is created, above and covering the first layer conductors 508. In process portion (vii), openings are created in the second component-side PID 510. In process portion (viii), additional metallization structures (512), such as vias and an additional metal layer, are created.

In process portion (ix), a third component-side PID 514 is created. In process portion (x), openings are created in the third component-side PID 514. In process portion (xi), second layer conductors 516 are created on and through the third component-side PID 514. These second layer conductors 516 may be a metal layer or a metallization layer, for example, and may be formed using gold, silver, copper, aluminum, or other conductive materials. In process portion (xii), solder balls 518 are mounted to at least some of the second layer conductors 516. In process portion (xiii), a passive component 520 is placed onto a portion of the now-exposed adhesive layer 504, i.e., in a portion of the carrier not covered by the first layer conductors 508 or second layer conductors 516. In process portion (xiv), a temporary bonding film 522 is applied, covering the structures (e.g., the solder balls 518 and the passive component 520) and providing a planar top surface. The partial process 500 continues in FIG. 5B.

Referring now to FIG. 5B, in process portion (xv), a second carrier 524 is attached to the temporary bonding film 522. In process portion (xvi), the existing assembly is flipped over. In process portion (xvii), the first carrier 501 and adhesive layer 504 are removed, exposing the first component-side PID 506. In process portion (xviii), openings are created in the first component-side PID 506 for front-side metallization layers. In process portion (xix), a first front-side metallization layer 526 is created that is electrically coupled to the passive component 520.

In process portion (xx), a first die-side PID 528 is created over the first front-side metallization layer 526. In process portion (xxi), openings are created in the first die-side PID 528, exposing the first front-side metallization layer 526. In process portion (xxii), a second front-side metallization layer 530 is created that is electrically coupled to the first front-side metallization layer 526. In process portion (xxiii), a second die-side PID 532 is created over the second front-side metallization layer 530, and openings are created in the second die-side PID 532 for copper pillar plating for die attachment. In process portion (xxiv), package-side copper pillars 534 are created for die-to-wafer attachment. The partial process 500 continues in FIG. 5C.

Referring now to FIG. 5C, in process step (xxv), a die 536 with an oxide layer 538 and die-side copper pillars 540 is attached to the package assembly such that the die-side copper pillars 540 are electrically coupled to the package-side copper pillars 534. In process step (xxvi), according to some aspects, the die-to-wafer attach process involves curing the package-and-die assembly at 150-250 degrees Celsius, which causes the oxide layer 538 to covalently bond with the second die-side PID 532 and which causes metal diffusion between the package-side copper pillars 534 and the die-side copper pillars 540. In process step (xxvii), the second carrier 524 and temporary bonding film 522 are removed. In this manner, a package 500 (similar to package 300) including the die 536 with passive component 520 in the recess formed in the substrate 502 including metallization layers 503 may be fabricated having a smaller critical distance (CD) compared to conventional packaging solutions.

It will be appreciated that the foregoing fabrication process was provided merely as general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

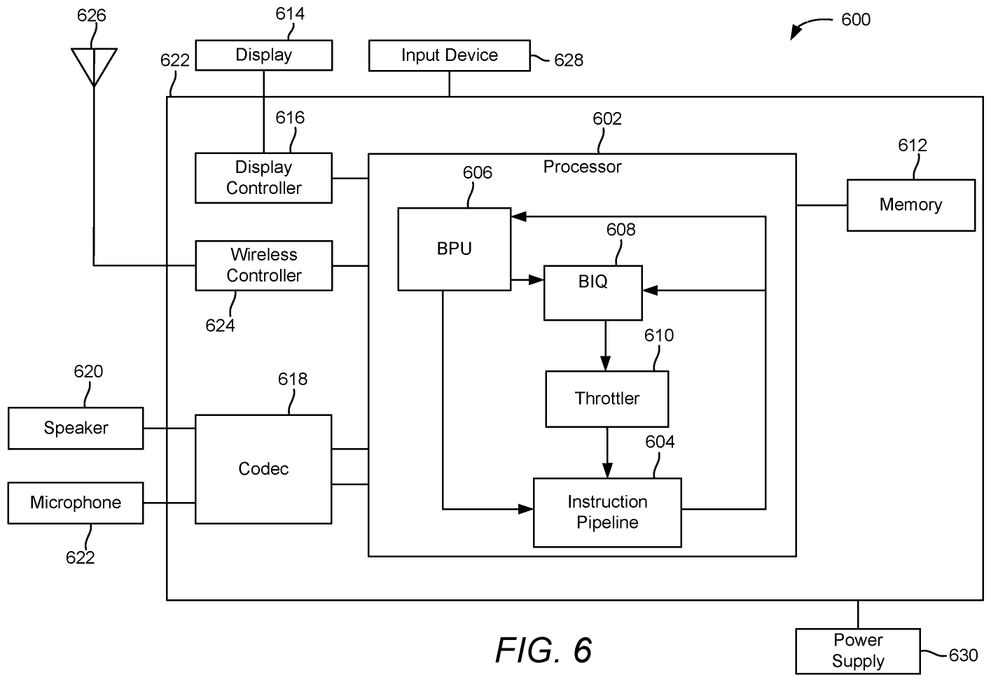

FIG. 6 illustrates an exemplary mobile device in accordance with some examples of the disclosure. Referring now to FIG. 6, a block diagram of a mobile device that is configured according to exemplary aspects is depicted and generally designated mobile device 600. In some aspects, mobile device 600 may be configured as a wireless communication device. As shown, mobile device 600 includes processor 602. Processor 602 is shown to comprise instruction pipeline 604, buffer processing unit (BPU) 606, branch instruction queue (BIQ) 608, and throttler 610 as is well known in the art. Other well-known details (e.g., counters, entries, confidence fields, weighted sum, comparator, etc.) of these blocks have been omitted from this view of processor 602 for the sake of clarity. Processor 602 may be communicatively coupled to memory 612 over a link, which may be a die-to-die or chip-to-chip link. Mobile device 600 also includes display 614 and display controller 616, with display controller 616 coupled to processor 602 and to display 614.

In some aspects, FIG. 6 may include coder/decoder (CODEC) 618 (e.g., an audio and/or voice CODEC) coupled to processor 602; speaker 620 and microphone 622 coupled to CODEC 618; and wireless controller circuits 624 (which may include a modem, radio frequency (RF) circuitry, filters, etc., which may be implemented using one or more flip-chip devices, as disclosed herein) coupled to wireless antenna 626 and to processor 602.

In a particular aspect, where one or more of the above-mentioned blocks are present, processor 602, display controller 616, memory 612, CODEC 618, and wireless controller circuits 624 can be included in a system-in-package or system-on-chip device, including but not limited to package 300, which may be implemented in whole or part using the techniques disclosed herein. Input device 628 (e.g., physical or virtual keyboard), power supply 630 (e.g., battery), display 614, input device 628, speaker 620, microphone 622, wireless antenna 626, and power supply 630 may be external to system-on-chip device and may be coupled to a component of system-on-chip device, such as an interface or a controller.

It should be noted that although FIG. 6 depicts a mobile device, the processor 602 and memory 612 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

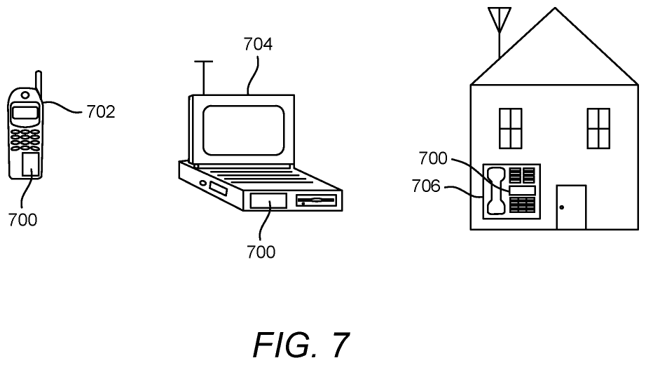

FIG. 7 illustrates various electronic devices that may be integrated with any of the aforementioned integrated device or semiconductor device accordance with various examples of the disclosure. For example, a mobile phone device 702, a laptop computer device 704, and a fixed location terminal device 706 may each be considered generally user equipment (UE) and may include a package 300 as described herein, for example. The package 300 may be, for example, any of the integrated circuits, dies, integrated devices, integrated device packages, integrated circuit devices, device packages, integrated circuit (IC) packages, package-on-package devices described herein. The mobile phone device 702, laptop computer device 704, and fixed location terminal device 706 illustrated in FIG. 7 are merely exemplary. Other electronic devices may also feature device including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed packages, devices, and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into a flip-chip or other package. The packages may then be employed in devices described herein.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

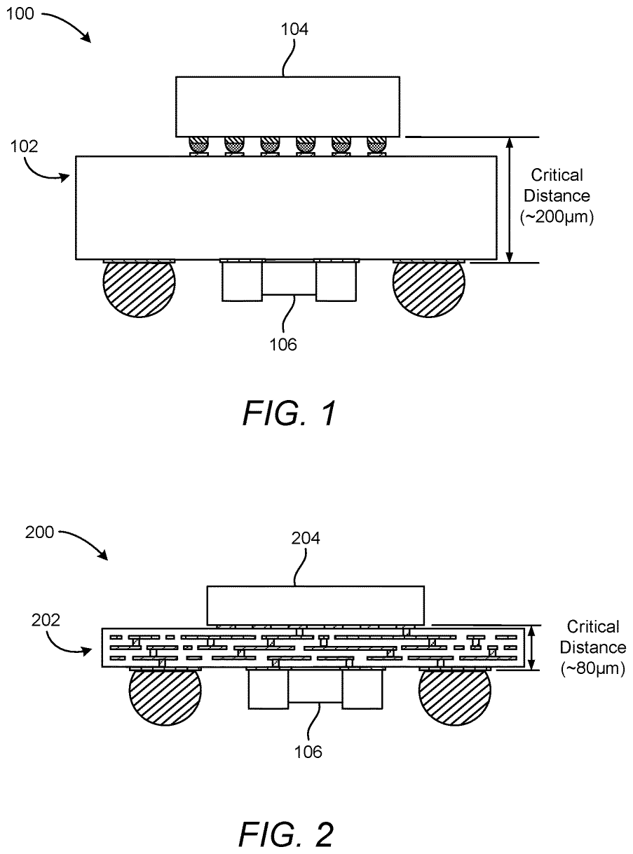

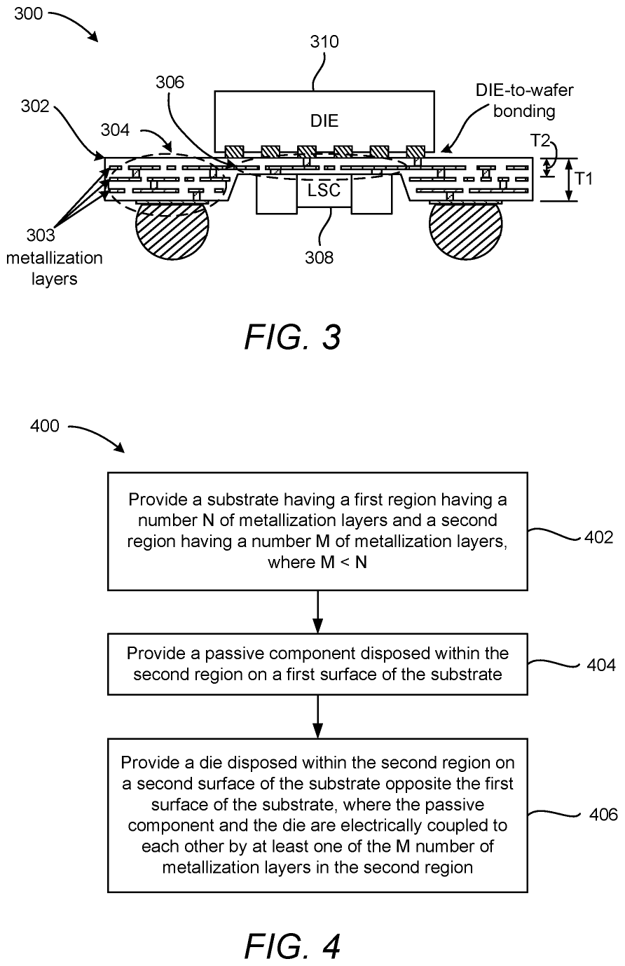

One or more of the components, processes, features, and/or functions illustrated in FIGS. 1-7 may be rearranged and/or combined into a single component, process, feature or function or incorporated in several components, processes, or functions. Additional elements, components, processes, and/or functions may also be added without departing from the disclosure. It should also be noted that FIGS. 1-7 and corresponding description in the present disclosure are not limited to dies and/or ICs. In some implementations, FIGS. 1-7 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), wide-band CDMA (W-CDMA), time division multiple access (TDMA), frequency division multiple access (FDMA), orthogonal frequency division multiplexing (OFDM), global system for mobile communications (GSM), the third generation partnership project (3GPP) long term evolution (LTE), fifth generation (5G) new radio (NR), Bluetooth (BT), Bluetooth low energy (BLE), IEEE 802.11 (WiFi), and IEEE 802.15.4 (Zigbee/Thread) or other protocols that may be used in a wireless communications network or a data communications network. Bluetooth low energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described hereby can be configured to perform at least a portion of a method described hereby.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

Further, those of skill in the art will appreciate that the various illustrative logical blocks, modules, circuits, and algorithm actions described in connection with the examples disclosed herein may be implemented as electronic hardware, computer software, or combinations of both. To clearly illustrate this interchangeability of hardware and software, various illustrative components, blocks, modules, circuits, and actions have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Although some aspects have been described in connection with a device, it goes without saying that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer or an electronic circuit. In some examples, some or a plurality of the most important method actions can be performed by such an apparatus.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or a plurality of claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A package, comprising:
a substrate having a first region comprising a number N of metallization layers and a second region comprising a number M of metallization layers, where M is less than N;
a passive component disposed within the second region on a first surface of the substrate; and
a die disposed within the second region on a second surface of the substrate opposite the first surface of the substrate, the die being electrically coupled to the passive component by at least one of the number M of metallization layers within the second region.

2. The package of claim 1, wherein the first region has a first thickness T1 and the second region has a second thickness T2 less than T1.

3. The package of claim 1, wherein M=1.

4. The package of claim 1, wherein M>1.

5. The package of claim 1, wherein the die is electrically coupled to the package using a die-to-wafer connection.

6. The package of claim 1, wherein the die is part of a flip-chip package.

7. The package of claim 1, wherein the passive component comprises a line-side component.

8. The package of claim 7, wherein the line-side component comprises a line-side capacitor, resistor, or inductor.

9. The package of claim 1, wherein the metallization layers comprise copper.

10. The package of claim 1, wherein the substrate comprises pre-preg (PPG).

11. The package of claim 1, wherein at least one metallization layer comprises a redistribution layer.

12. A method for fabricating a package, the method comprising:
providing a substrate having a first region comprising a number N of metallization layers and a second region comprising a number M of metallization layers, where M is less than N;
providing a passive component disposed within the second region on a first surface of the substrate; and
providing a die disposed within the second region on a second surface of the substrate opposite the first surface of the substrate, the die being electrically coupled to the passive component by at least one of the number M of metallization layers within the second region.

13. The method of claim 12, wherein the first region has a first thickness T1 and the second region has a second thickness T2 less than T1.

14. The method of claim 12, wherein M=1.

15. The method of claim 12, wherein M>1.

16. The method of claim 12, wherein the die is electrically coupled to the package using a die-to-wafer connection.

17. The method of claim 12, wherein the die is part of a flip-chip package.

18. The method of claim 12, wherein the passive component comprises a line-side component.

19. The method of claim 18, wherein the line-side component comprises a line-side capacitor, resistor, or inductor.

20. The method of claim 12, wherein the metallization layers comprise copper.

21. The method of claim 12, wherein the substrate comprises pre-preg (PPG).

22. The method of claim 12, wherein at least one metallization layer comprises a redistribution layer.
